(19) United States
(12) Patent Application Publication
(10) Pub. No.: US 2024/0079334 A1
(43) Pub. Date: Mar. 7, 2024

(54) SEMICONDUCTOR PACKAGE INCLUDING GLASS INTERPOSER STRUCTURE WITH SELF-ALIGNED THROUGH GLASS VIAS

(71) Applicant: Intel Corporation, Santa Clara, CA (US)

(72) Inventors: Jeremy D. Ecton, Gilbert, AZ (US); Brandon Christian Marin, Gilbert, AZ (US); Srinivas V. Pietambaram, Chandler, AZ (US); Suddhasattwa Nad, Chandler, AZ (US); Gang Duan, Chandler, AZ (US)

(73) Assignee: Intel Corporation, Santa Clara, CA (US)

(21) Appl. No.: 17/903,856

(22) Filed: Sep. 6, 2022

(51) Int. Cl. H01L 23/538; H01L 21/48; H01L 23/15; H01L 23/498; H01L 25/065

(52) U.S. Cl. CPC H01L 23/5381; H01L 21/4857; H01L 21/486; H01L 23/15; H01L 23/49822; H01L 23/49838; H01L 23/5383; H01L 23/5386; H01L 25/0655; H01L 24/16

(57) ABSTRACT

A microelectronic structure, a semiconductor package including the structure, an IC device assembly including the structure, and a method of making the structure. The microelectronic structure includes: a first buildup layer and a second buildup layer including respective first and second electrically conductive structures; and a bridge layer including a glass material extending across a width thereof, the bridge layer between the first buildup layer and the second buildup layer and comprising: an interconnect bridge including third electrically conductive structures coupling a first set of the first electrically conductive structures to a second set of the first electrically conductive structures. Through glass vias (TGVs) extending from a top surface to a bottom surface of the bridge layer, the TGVs coupling a third set of the first electrically conductive structures to at least some of the second electrically conductive structures.

### TECHNICAL FIELD

This disclosure relates generally to die-to-die (D2D) in-package interconnect technology.

### BACKGROUND

In-package die-to-die (D2D) interconnect technologies include, at a high level, standard interconnect regimes and advanced interconnect regimes to provide signal connection between two dies provided on a top surface of the package substrate. A standard interconnect regime involves the provision of signal routing traces typically within organic build-up layers of the package substrate to couple the two dies to one another. An advanced interconnect regime provides a silicon bridge structure as an interconnect bridge embedded within a package substrate, where the silicon bridge structure includes signal routing traces therein to couple the two dies to one another. An example of a silicon bridge structure for an advanced package interconnect regime includes, for example, and embedded multi-die interconnect bridge (EMIB), or a chip-on-wafer-on-substrate (CoWoS). A given D2D interconnect technology or regime may be selected based on a number of factors, such as, for example, bandwidth density requirements (e.g. bandwidth per millimeter (BW/mm) and/or BW/mm\hat{ }2), a die/package desired floorplan, and available form factors.

As the number of interconnect bridges to be embedded in a microelectronic assembly increases, the cost and yield of embedding may suffer.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 is a cross sectional view of a microelectronic assembly including an example of a standard interconnect regime.

FIG. 2 is a cross sectional view of a microelectronic assembly including an example of interconnect regime including an interconnect bridge embedded in a package substrate according to an embodiment.

FIG. 3 is a cross sectional view of a microelectronic assembly according to a first embodiment.

FIGS. 4A-4I show respective stages for the formation of the microelectronic assembly of FIG. 3.

FIG. 5 is a cross sectional view of a microelectronic assembly according to a second embodiment.

FIG. 6 is a flow chart of a process according to some embodiments.

FIG. 7 is a cross-sectional side view of an integrated circuit device assembly that may include a microelectronic structure in accordance with any of the embodiments disclosed herein.

FIG. 8 is a block diagram of an example electrical device that may include a microelectronic structure, in accordance with any of the embodiments disclosed herein.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

The technologies described herein may be implemented in one or more electronic devices. Non-limiting examples of electronic devices that may utilize the technologies described herein include any kind of mobile device and/or stationary device, such as microelectromechanical systems (MEMS) based electrical systems, gyroscopes, advanced driving assistance systems (ADAS), 5G communication systems, cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments, the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices, including semiconductor packages with passive heat spreaders, interface layers, TIMs, top dies, side dies, substrates, and package substrates.

As used herein the terms “top,” “bottom,” “cupper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

As used herein, reference to a “die” is meant to broadly refer to a die, a chiplet, a chip complex, a chiplet complex, or any other integrated circuit structure including circuitry therein supported on a substrate. While the terms die, chip, and chiplet may be used interchangeably, the term chiplet is sometimes used to refer to an integrated circuit die that implements a subset of the functionality of a larger integrated circuit component, the larger integrated circuit component formed using one or more chiplets connected by inter-die interconnects (e.g., interposers, bridges, local interconnect components, local silicon interconnects). The use of chiplets in integrated circuit components has become attractive as feature sizes have reduced and the demand for high-performance larger integrated circuit components has increased. The approach of assembling multiple known-good dies (chiplets) to form a larger integrated circuit component results in improved manufacturing efficiencies as the overall yield of an integrated circuit component assembled from multiple small chiplets is better than that of an integrated circuit component in which the functionality of the chiplets is implemented on a single large integrated circuit die. Any integrated circuit die, chip, or chiplet can implement any portion of the functionality of any processor unit described or referenced herein.

As used herein, the term “electronic component” can refer to an active electronic circuit (e.g., processing unit, memory, storage device, FET) or a passive electronic circuit (e.g., resistor, inductor, capacitor).

As used herein, the term “the material” of component A may refer to one or to more constituent materials of component A. For example, where component A includes 3 sublayers made of three respective materials X, Y and Z, the disclosure herein may refer to “the material of component A” to refer to materials X, Y and Z that make up component A.

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

The demand for miniaturization of form factor and increased levels of integration for high performance in the semiconductor industry are driving sophisticated packaging approaches. For example, die partitioning has enabled both miniaturization of small form factor and high performance without yield issues. Die partitioning requires fine die to die interconnections. Interconnect bridges, such as Embedded Multi-die Interconnect Bridges (EMIBs) pioneered and developed by Intel, represent a breakthrough technology that enables a lower cost and simpler 2.5D (e.g., interposer) packaging approach for very high-density interconnects between heterogeneous dies on a single microelectronic assembly (e.g.; printed circuit board). Instead of an expensive silicon interposer with TSVs (through silicon vias), interconnect bridges typically involve a small silicon bridge chip embedded in a package substrate, enabling very high density die-to-die connections only where needed. Standard flip-chip assembly is then typically used for robust power delivery and to connect high-speed signals directly from chip to the package substrate.

For future generations of die partitioning, several bridges that can connect the dies at much finer contact pitches (25 microns or lower) than those currently in use may be needed. The interconnect bridge approach suffers from a high cumulative Bump Thickness Variation (BTV) as contact pitches shrink. As the number of interconnect bridges to be embedded increases, the cost and yield of embedding may suffer.

Alternate architectures and/or approaches such as an interconnect bridge with through silicon vias (TSVs) can lead to cost savings and the ability to optimize package substrates by node sometimes can make an interconnect bridge with TSVs (e.g., an EMIB-T) the approach of choice. Some solutions have proposed an interconnect bridge with TSVs along with an active functional die. Fine die-to-die interconnections for die tiling can be accomplished through this embedded die approach.

Another option for enabling fine die-to-die interconnections is incorporating a thin glass core into the substrate package. Glass core compared to conventional epoxy core offers several advantages including a higher PTH density, lower signal losses, lower total thickness variation (TTV), among others.

Another option being explored has involved inserting a silicon bridge into a nested glass interposer, that is, into a cavity of a glass interposer. Such an approach requires placing a bridge inside of a glass cavity. Some major drawbacks with this approach include its complexity, a need for precise cavity drilling, for cavity filling, and for encapsulation. In particular, significant cavity depth variation (+/−10%) have sometimes been observed with the latter approach. Additionally, the cavity may not be flat resulting in tilt of the final position of the silicon bridge in the cavity. Thus solutions that can accommodate high cavity depth variation and/or non-flat surfaces are preferred.

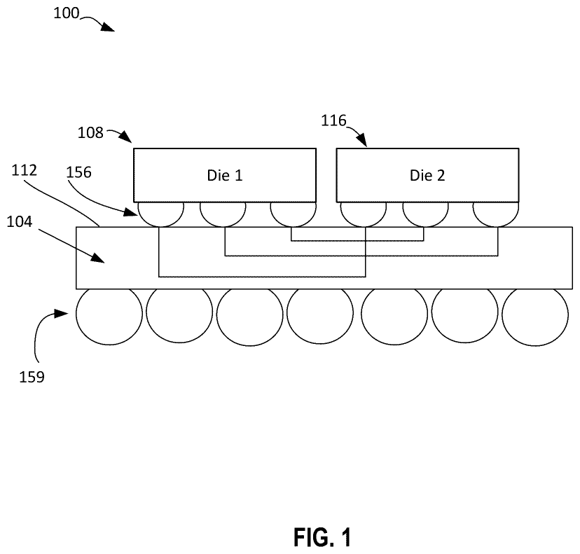

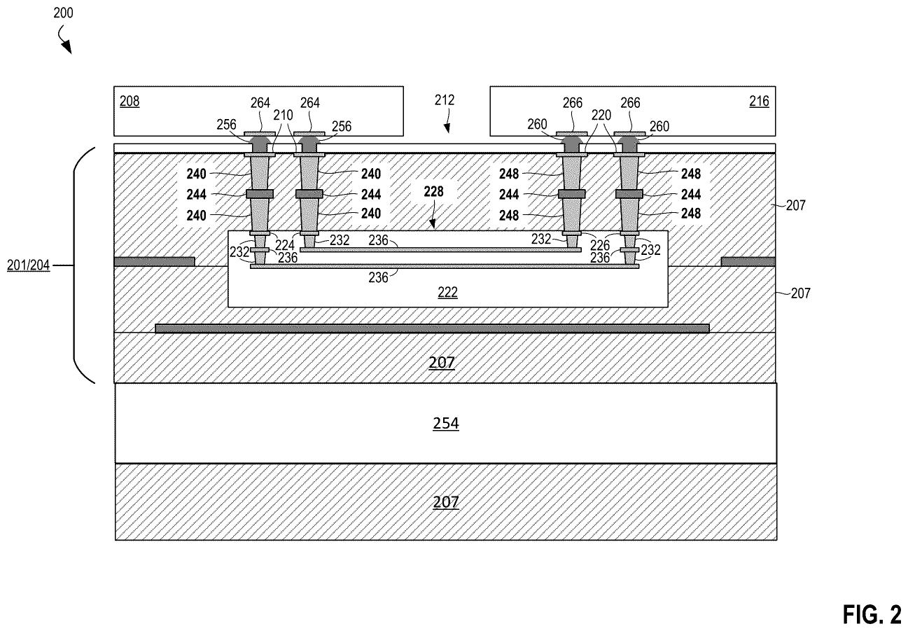

An explanation will now follow below regarding the state-of-the-art in the context of FIGS. 1 and 2.

FIG. 1 is a cross-sectional view of an example microelectronic assembly or semiconductor package 100 including a package substrate 104, and two dies 108 and 116 supported on a top surface 112 of the package substrate 104. In FIG. 1, the package substrate 104 is shown as including signal routing traces 136 therein coupling die 108 to die 116. Substrate 104 may include a core layer including sublayers of a non-conductive material, such as glass, silicon or an organic material, and the traces 136 extending through the sublayers to conduct electrical signals therethrough. Dies 108 and 116 are each electrically coupled to a top surface 112 of the package substrate 104 via electrical contact structures or joints 156, such as C4 bumps, connecting to die conductive contacts on the respective dies and substrate conductive contacts (not shown). The C4 bumps couple the dies 108 and 116 together by way of traces 136 extending through the package substrate 104 and providing conductive pathways between the dies 108 and 116. Additional electrically conductive structures 159 are provided at a bottom surface of the package substrate.

FIG. 2 is a cross-sectional view of an example microelectronic assembly or semiconductor package 200 including an interconnect bridge 222 embedded within a package substrate 204, and two dies 208 and 216 supported on a top surface 212 of the package substrate 204. In FIG. 2, the combination of the package substrate 204 and interconnect bridge 222 will together be referred to as a printed circuit board 201. Substrate 204 may include a core layer 254, and build-up layers (BULs) 207 on a top and bottom surface of the core layer 254. The build-up layers may include successive non-conductive layers and successive metal layers (or redistribution layers (RDLs); e.g. M1, M2, . . . Mn) between the dielectric layers. The non-conductive layers may include a non-conductive material, such as glass, silicon or an organic material. RDLs include conductive traces 240 and 244 extending through the sublayers to conduct electrical signals therethrough. A first integrated circuit die 208 is attached to a top surface 212 of the package substrate 204 via electrical contact structures or joints 256 connecting to die conductive contacts 264 and substrate conductive contacts 210. A second integrated circuit die 216 is attached to top surface 212 via electrical contact structures 260 connecting to die conductive contacts 266 and substrate conductive contacts 220.

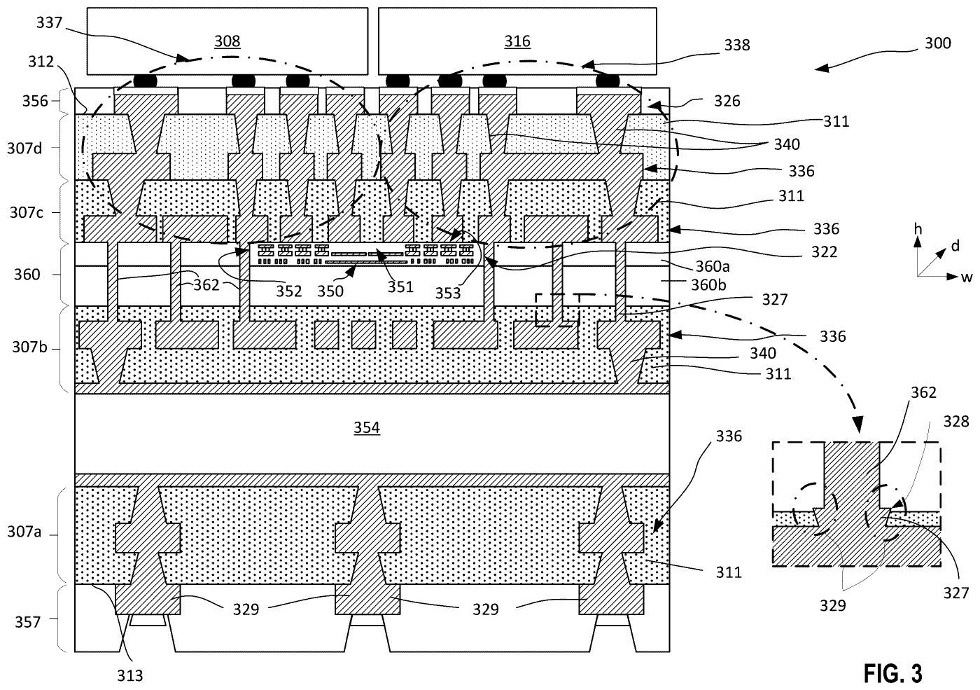

The build-up layers 207, although shown in FIG. 2 (and in subsequent FIGS. 3A-3I, 4, 5, and 6) as a handful of layers, there can be any number of build-up sublayers in a semiconductor package. For example, in server applications, there can be up to 10 build-up layers. In various embodiments, a build-up layer comprises a dielectric material and may include a suitable nitride or oxide, such as silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen). In some embodiments, a build-up layer comprises a photo-imagable dielectric (PID). In some embodiments, a build-up layer comprises an Ajinomoto Build-Up film (often referred to as ABF), which is a material that comprises an organic resin matrix with different types of fillers (for example, silica fillers of different sizes, or hollow fillers of different sizes) to control the coefficient of thermal expansion (CTE) and/or electrical properties of the build-up layers (e.g., the dielectric constant (Dk), and/or dissipation factor (insertion loss) (Df)).

In some embodiments, it is advantageous for the build-up layers to have a CTE that matches that of integrated circuit dies (e.g., match the CTE of silicon) attached to a panel substrate. In some embodiments, the dielectric material of a build-up layer can have a CTE that is close (e.g., within 10%) to that of silicon. In other embodiments, the dielectric material of a build-up layer can be any type of epoxy molding compound. build-up layers may include a metal layer comprising conductive traces (or metal lines), metals used for interconnect metals in the build-up layer include copper or other suitable metal.

Referring still to FIG. 2, bridge conductive contacts 224 and 226 are located on a face 228 of the bridge 200. Bridge vias 232 and bridge conductive traces 236 provide conductive pathways between the conductive contacts 224 and 226. Substrate vias 240 and substrate conductive traces 244 provide conductive pathways from the substrate conductive contacts 210 to the bridge conductive contacts 224 and substrate vias 248 and substrate conductive traces 244 provide conductive pathways from the substrate conductive contacts 220 to the bridge conductive contacts 226. Together, conductive contacts 210, 220, 224, 226, vias 232, 240, 248, and conductive traces, 236, 244 provide conductive pathways between integrated circuit dies 208 and 216 and thus allow them to be communicatively coupled.

Although the embedded interconnect bridge 222 is shown as being fully embedded within the substrate 204, in some embodiments, it can be partially embedded, with the bridge face 228 being part of the face 212 of the first substrate component 204. In such embodiments, the bridge conductive contacts 224 and 226 can be located at the face 212 of the substrate component 204 and the integrated circuit dies 208 and 216 can connect to the bridge conductive contacts 224 and 226 via coupling components 256 and 260, respectively.

Many of the elements of the semiconductor package 100 of FIG. 1 or 200 of FIG. 2 are included in other ones of the accompanying drawings relating to some embodiments, for example FIGS. 3, 4A-4I and 5. A description of some elements may therefore not be repeated when discussing the drawings to be described below, and any of these elements may take any of the forms disclosed herein.

In addition, in the below descriptions of FIGS. 3, 4A-4I and 5, although reference may be made to bumps to refer to the electrical contact structures coupling dies to a package substrate, embodiments are not so limited, and include within their scope the provision of electrical contact structures such as electrical contact structures in the form of contact pads, pins or wire bonds based on application needs.

FIG. 3 is a cross-sectional view of an example microelectronic assembly or semiconductor package 300 according to some embodiments. Package substrate 304, which includes build-up layers 307a-307d, is shown together with an interconnect bridge 322 embedded therein (an in-package interconnect bridge). The combination of the package substrate 304 and interconnect bridge 322 corresponds to a microelectronic structure in the form of a printed circuit board 301.

The substrate 304 may, by way of example, have a thickness that is in a range of substantially 0.05 mm to substantially 3 mm, wherein substantially equals+/−10%), and may comprise one or more build-up or build-up layers 307a, 307b, 307c, and 307d. Persons with skill in the art may appreciate that the distinctions in the various build-up layers attributed to the build-up layers 307a-307d in this discussion have been introduced for illustrative purposes; in a cross-sectional image of the substrate 304, such as by a transmission electron microscope (TEM), the layers 307a-307d may be indistinguishable, and different from the ones shown in the figure, and there may be more or less of the build-up layers than the ones shown.

Region 337, on the left of the page, includes electrically conductive structures that provide signal communication for die 308, and on the right, region 338 includes electrically conductive structures that provide signal communication for die 316. Electrically conductive structures of the substrate 304 may include traces 306 (including for example contacts), and vias 340. Traces 336 may be arranged to route electrical signals in a horizontal direction, and vias 340 may be arranged to route electrical signals in a vertical direction. The electrically conductive structures may include an electrically conductive material such as a metal (e.g., copper, aluminum, nickel, cobalt, iron, tin, gold, silver, or combinations thereof). A passivation layer 356 in the form of solder resist or other dielectric material on the upper substrate surface 312 of substrate 304 may be patterned with a respective pinouts (physical arrangement of conductive contacts 326 at a respective pitch) for individual dies such as dies 308 and 316. Signal routing may occur from at least one conductive contact of the first set of conductive contacts 326 coupled to die 306 to at least one conductive contact of the second set of conductive contacts 326 coupled to die 318, the signal routing being via the interconnect bridge 322. A passivation layer 357 in the form of solder resist or other dielectric material on the lower substrate surface 313 of substrate 304 may also be patterned with a respective pinouts (physical arrangement of conductive contacts 329 at a respective pitch) for electrical coupling of the microelectronic assembly 300 to another component, such as a motherboard. The buildup layers may further include a non-conductive material 311 within which the traces 336 and vias 340 may be embedded. The non-conductive material may include a dielectric material, such as those listed by way of example in the context of build-up layers 207 of FIG. 2 above.

In the microelectronic assembly of FIG. 3, where a first die and a second die are coupled to one another through an in-package interconnect bridge 322, each active RX circuitry of the first die is coupled through the in-package D2D interconnects to a corresponding active TX circuitry of the second die, and each active TX circuitry of the first die is coupled through the in-package D2D interconnects to a corresponding active RX circuitry of the second die.

Substrate 304 as shown corresponds to a microelectronic structure in the form of a printed circuit board that may include a core layer 354. There could be through-vias (not shown) penetrating through the core layer 354 and electrically connecting the plurality of RDLs across the core layer 354. The core layer 110 may be a core substrate, and may be disposed in a center of the printed circuit board 301. The core layer 110 may have a multilayer configuration. In this case, a better warpage control effect may be obtained and a plurality of passive components (not shown) may be more easily embedded into the core layer 354. For example, the core layer 110 may include a plurality of insulating layers that are bonded together by a plurality of bonding layers disposed therebetween. Bonding layers could also bet disposed on the top and bottom surfaces of the core to bond the same to build-up layers 307b and 307a, respectively. The core layer 354 may include one or more insulating materials, such as, for example, at least one of a thermosetting resin such as an epoxy resin, a thermoplastic resin such as polyimide, or a material including the thermosetting resin and the thermoplastic resin, a glass fiber (or a glass cloth or a glass fabric, an inorganic filler, and/or a reinforcing material such as an inorganic filler, for example, a copper clad laminate (CCL), an unclad CCL, or the like). Alternatively, the material of the core layer 354 may include, for example, a liquid crystal polymer (LCP). Where bonding layers are used, they may include, for example, at least one of a thermosetting resin such as an epoxy resin, a thermoplastic resin such as polyimide, or a material including the thermosetting resin and the thermoplastic resin, a glass fiber, and/or a reinforcing material such as an inorganic filler, for example, prepreg (PPG), Ajinomoto Build-up Film (ABF), and the like.

The interconnect bridge 322 may include electrically conductive structures 350 therein including traces and vias. interconnect bridge 322 may in addition include bridge devices 352, including one or more of passive or active devices. Such devices may include, but are not limited to, capacitors, decoupling capacitors, resistors, inductors, fuses, diodes, transformers, sensors, electrostatic discharge (ESD) devices, and memory devices.

Interconnect bridge 322 is part of a bridge layer 360 which may include a first bridge sublayer 360a, and a second bridge sublayer 360b. Each of sublayers 360a and 360b may include its own sublayers. One or more of bridge sublayers 360a or 360b may include glass, such as a silicon oxide, a silicon dioxide or a borosilicate glass material. Bridge layer 360 may have a width W such that it includes one or more through glass vias (TGVs) therein that is in registration with a via of a closest adjacent build-up layer. Thus, bridge layer 360 includes electrically conductive TGVs 362 extending therethrough, and in registration with vias 327 of immediately adjacent underlying buildup layer 307b. Buildup layer is thus in contact with extends over at least one via of an immediately adjacent buildup layer.

As used herein, “in registration with” means at least partially aligned with, or at least partially overlapping with. Thus, the TGVs of the bridge layer 360 may be aligned, either fully or partially, with vias of the underlying build-up layer.

According to an embodiment, the bridge layer 360 is co-extensive with at least one of the closest underlying buildup layer 307b or closest overlying buildup layer 307a, in at least one of a width direction w or depth direction d of buildup layers 307a and 307b. According to an alternative embodiment, the bridge layer 360 is not coextensive in at least one of the w direction or the d direction with one or more of the closest overlying or closest underlying buildup layer.

Bridge sublayer 360b supports bridge sublayer 360a thereon. Bridge sublayer 360a includes the interconnect bridge 322. Bridge 322 includes a non-conductive material 351 within which electrically conductive structures 350 and any bridge devices 352 are embedded.

According to one embodiment, the electrically conductive structures 350 of interconnect bridge 322, may include traces, vias, and contact pads 353. Optionally, the bridge device 322 may include bridge devices 352. Individual features of electrically conductive structures 350 may have dimensions in a height direction h and in a width direction w that may be at least ⅓ smaller, for example between about ⅓ smaller and about 1/10 smaller, than dimensions of electrically conductive structures such as traces 336 and vias 340 of the build-up layers 307a to 307d of the printed circuit board 301 that includes the interconnect bridge 322. For example, as considered based on the cross-section shown in FIG. 3, a height (or thickness) of non-conductive layers 351 of interconnect bridge 322 may be about 4 microns, a height (or thickness) of metallization layers (e.g., traces) within interconnect bridge 322 may be about 2 microns, and pitches between metallization layers in the w direction may be between 2-3 microns. However, a height (or thickness) of non-conductive layers 311 of each of the build-up layers may be in the tens of microns, a height (or thickness) of metallization layers (e.g., traces) 336 may be about 9 microns to 20 microns or more.

The electrically conductive structure 350 and bridge devices 352 may, according to one embodiment, as shown, be patterned into the bridge sublayer 360b. In the case of the latter, the non-conductive material 351 of the interconnect bridge may be integral with (form a one-piece structure with) a non-conductive material of at least one portion of the bridge sublayer 360a through which portion one or more of the TGVs 362 extend. If the bridge sublayer 360a (which includes the interconnect bridge 322) includes its own sublayers, then, according to this latter embodiment, the non-conductive material 351 may include interconnect bridge non-conductive sublayers that are integral with corresponding ones of the sublayers of the bridge sublayer 360a.

According to another embodiment, the interconnect bridge 322 may be inside a cavity defined in the bridge layer 360 (this embodiment is not shown). In such a case, the one or more TGVs 362 would be on one or more sides of the cavity, and in registration with corresponding vias 327 of the underlying buildup layer 307b.

According to an embodiment, the non-conductive material 351 of the interconnect bridge 322 may be a non-glass material, such as a non-glass material, such as, for example, a material including silicon.

According to another embodiment, the non-conductive material of bridge layer 360 may include a non-glass material, such as, for example, a material including silicon.

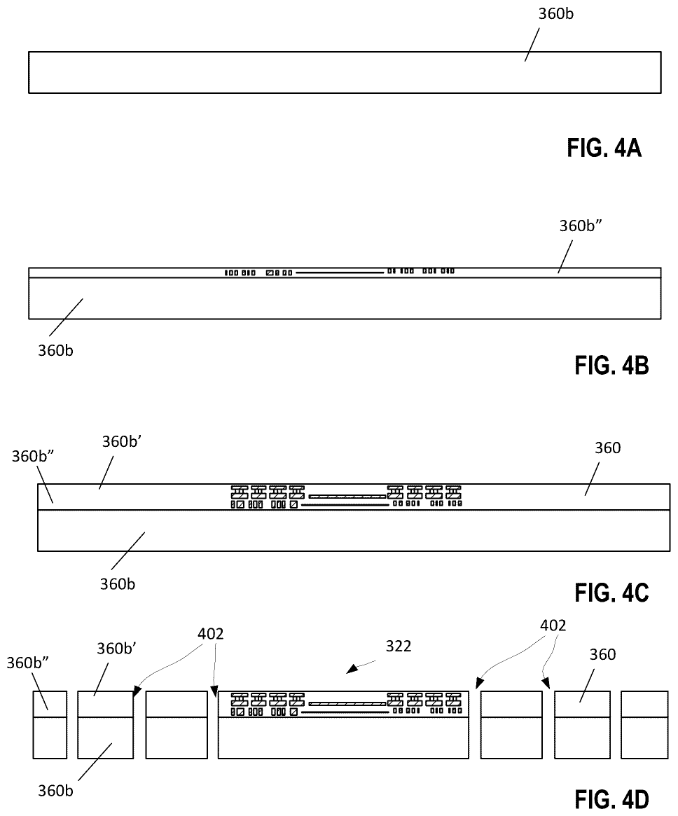

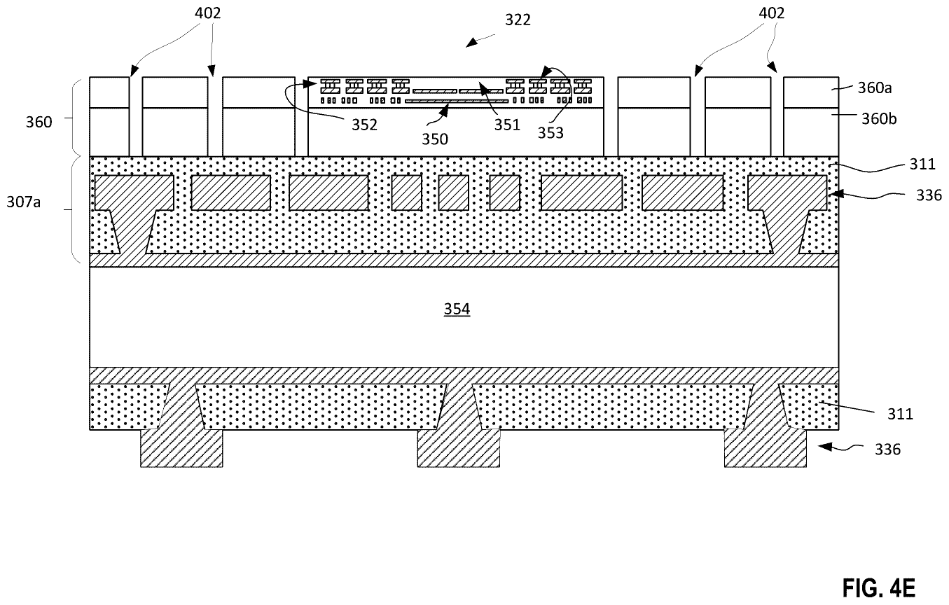

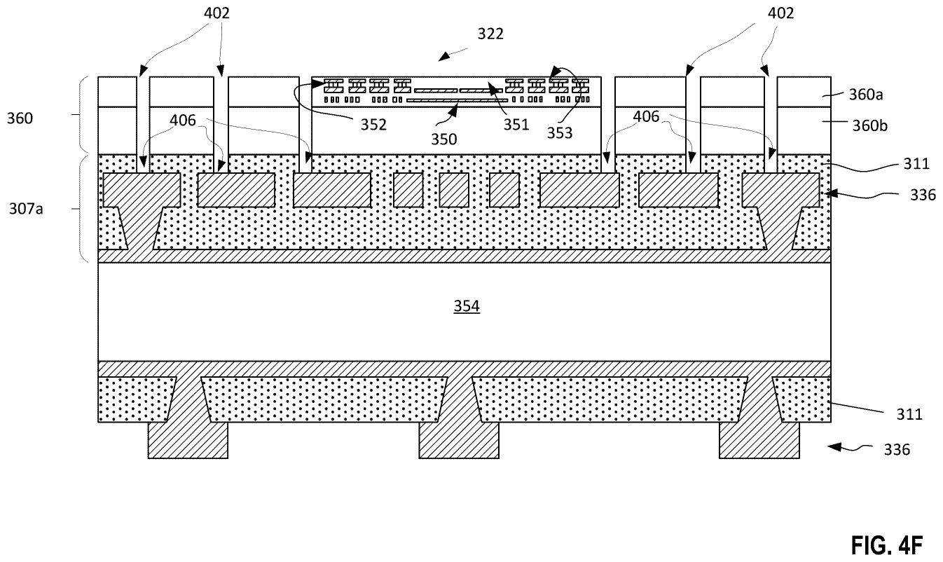

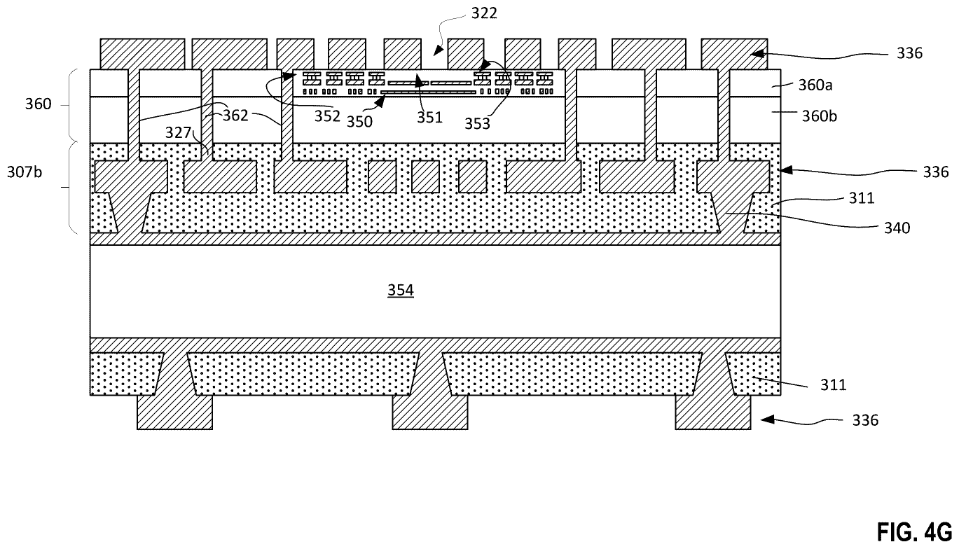

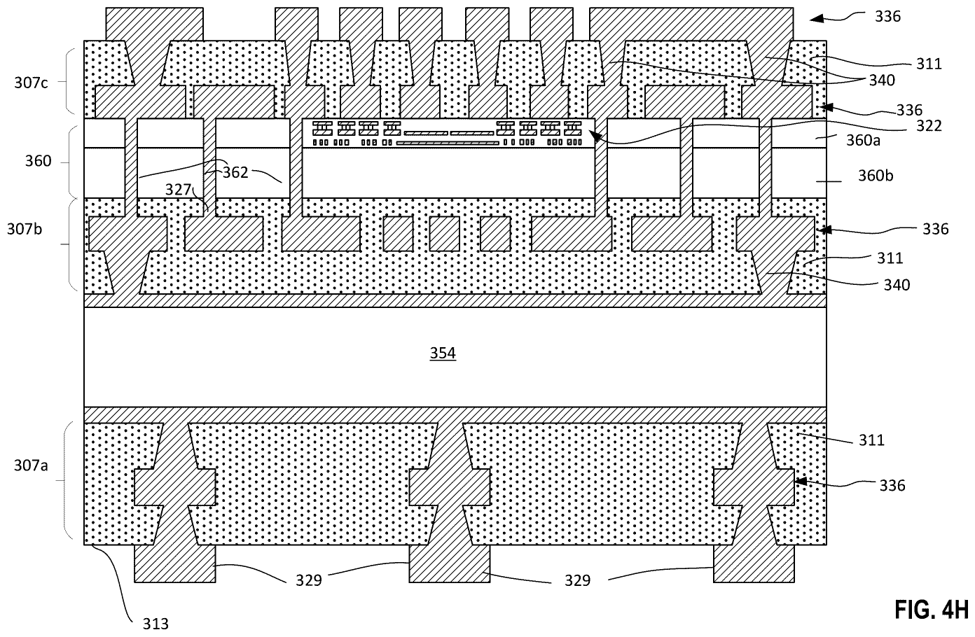

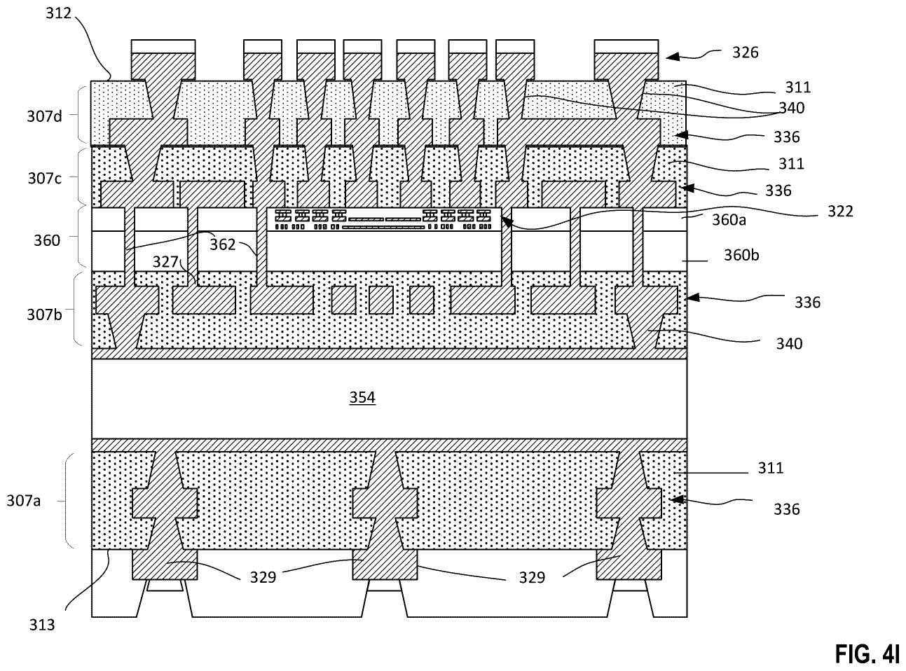

According to an embodiment, vias 327 within the closest (relative to the bridge layer 360) underlying buildup layer 307b define, an expanded portion 328 that extends within an underetch region 331 such that it presents a surface that contacts a lower surface of the bridge layer 360. Thus, while TGVs 362 are in registration with vias 327, vias 327 may be wider, at least at a top region thereof, than a width of the TGVs 362. The expanded portion 328 may be formed when the TGVs 362 are self aligned with vias 327 during formation, as will be explained in further detail in the context of FIGS. 4E, 4F and 4G.

Embodiments may provide a number of advantages. One such advantage is an elimination for a necessity to create a cavity in a package substrate for the provision of an interconnect bridge therein. In this manner, the necessity to align an interconnect bridge to a cavity and to level the same within the cavity can be mitigated, as noted above with respect to disadvantages of the state of the art. Embodiments thus provide a potentially simpler architecture and fabrication process. Some embodiments advantageously make possible a solderless attach to an interconnect bridge for improved power delivery, for example by allowing interconnect bridge attach by pressing the same onto a ABF of the underlying buildup layer.

Reference is now made to FIGS. 4A-4I, which show stages for fabricating a printed circuit board similar to printed circuit board 301 of FIG. 3.

FIG. 4A involves the provision of a first bridge sublayer including glass, the first bridge sublayer corresponding to bridge sublayer 360b of FIG. 3. The glass material of bridge sublayer 360b may include silicon, and, in addition, optionally at least one of oxygen or boron. For example, the glass material of bridge sublayer 360b may include silicon, silicon oxide, silicon dioxide, or a borosilicate material.

FIGS. 4B and 4C show a second bridge sublayer having been provided, the second bridge sublayer corresponding to bridge sublayer 360a of FIG. 3. Second bridge sublayer 360b includes an interconnect bridge 322 patterned therein. Interconnect bridge 322 includes electrical features therein, which electrical features include electrically conductive structures therein, including traces, and vias. The electrical features of second bridge sublayer 360b further include bridge devices 352, which could be active or passive or both. The electrical features of the interconnect bridge may be patterned as part of second bridge sublayer 360b, for example using RDL patterning on the glass material of the second bridge sublayer 360b. To perform RDL patterning on glass, laser etching of the glass may be performed by way of example, followed by a laser etch of the glass, following by RDL patterning. A damascene process may be used for the latter including etching of the glass, plating of the electrically conductive material, and possible polishing such as by way of chemical mechanical polishing (CM). The provision of the second bridge sublayer 360b may begin at FIG. 4B with the provision of a first layer 360b″ of sublayer 360b, which first layer 361b′ may include a first set of electrical features of the interconnect bridge patterned therein. Thereafter, the provision of the second bridge sublayer 360b may follow as shown in FIG. 4C with providing a second layer 360b′ on the first layer 360b″. The second layer 360b′ incudes additional electrical features such as additional traces, vias, contact pads 353, an possible additional bridge devices.

FIG. 4D shows the architecture of FIG. 4C, with the additional provision of TGV openings 402 through the bridge layer 360 at portions of the bridge layer 360 that do not coincide with the interconnect bridge 322. The TGV openings may be provided through etching, for example through laser etching.

FIG. 4E shows the architecture of FIG. 4D, in the form of an interposer including the sublayers 360a and 360b along with interconnect bridge 322 being attached onto an underlying multilayer structure that includes the core 354, passivation layer 357, and buildup layer 307b (minus vias 327) as already described above. The interposer attach may be performed using a bond film, such as any of the bond films described above, or it may be performed by pressing the interposer onto the material of the non-conductive layer 311 of buildup layer 307b.

FIG. 4F shows the architecture of FIG. 4E after it having been subjected to an etch process to provide a self-aligned via openings self-aligning TFV openings 402 with openings 404 of the underlying buildup layer 307b. Self-aligning takes place by virtue of the TGV openings 402 being used to mask the underlying non-conductive material 311 of buildup layer 307b in order to etch the same to provide openings 404 therein. The etch may be a dry etch.

FIG. 4G shows the architecture of FIG. 4E after provision of TGVs 362 by filling openings 402 with an electrically conductive material, and provision of vias 327 by filling openings 404 with an electrically conductive material. The vias may be filled by using a plating process, and openings 402 and 404, since they are in registration, may be filled with the electrically conductive material at the same time. In addition, traces 336 are shown as having been provided on a top surface of the bridge layer 360. Traces 336 may be provided using any known method, such as plating and patterning.

FIG. 4H shows the architecture of FIG. 4G after provision of buildup layer 307c, along with overlying traces 336. The non-conductive material 311 of the buildup layer, the vias therein, and the traces 336 may be provided in a well known manner as described previously.

FIG. 4I shows the architecture of FIG. 4H after provision of buildup layer 307d and passivation layer 356 thereon. The buildup layer 307d and passivation layer 356 may be provided in a well known manner as described previously. Provision of dies 308 and 316 atop the passivation layer as shown in FIG. 3 would then lead to the fabrication of a semiconductor package 300 of FIG. 3.

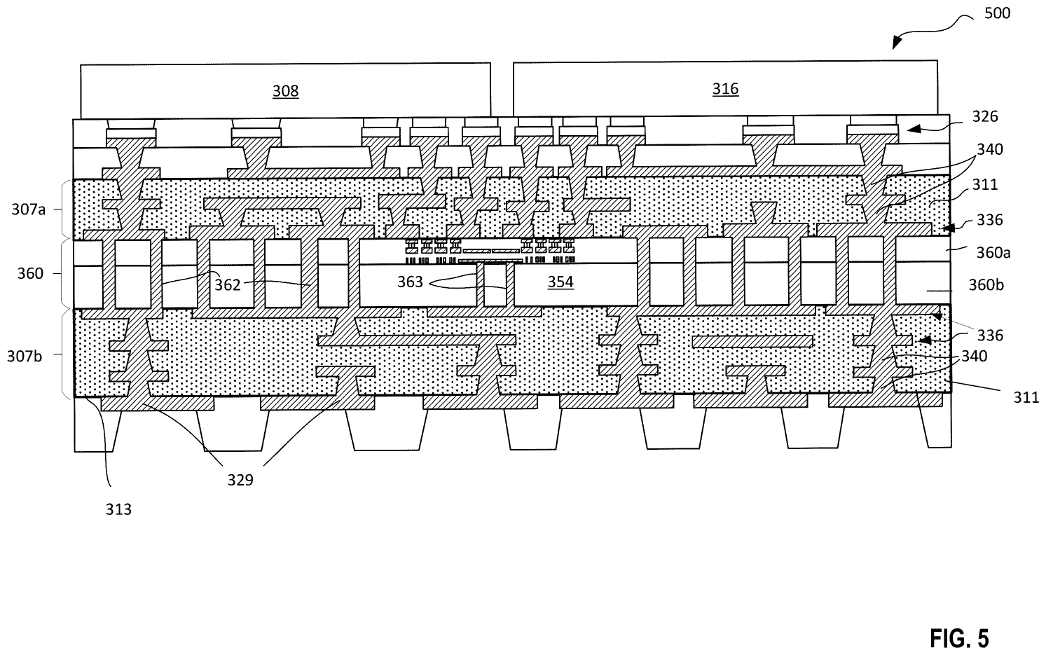

Reference is made to FIG. 5, which is a cross-sectional view of an example microelectronic assembly or semiconductor package 500 similar to that of FIG. 3, but according to a second embodiment. Here, an interconnect bridge 322 is provided in the core layer 354 of the semiconductor package 300. Thus, here, bride layer 360 corresponds to core 354. In addition, this embodiment includes TGVs 363 in the bridge layer 360/core 354 extending to the interconnect bridge 322 from a bottom region thereof, in addition to TGVs 362 in the bridge layer 360/core 354 connecting electrically conductive structures of two distinct buildup layers 307a and 307b to one another. Such an approach eliminates the need for a self-aligned attach involving vias in registration with one another as in the case of FIGS. 3, and 4E-4G, and makes the bottom electrical connection to the interconnect bridge 322 possible.

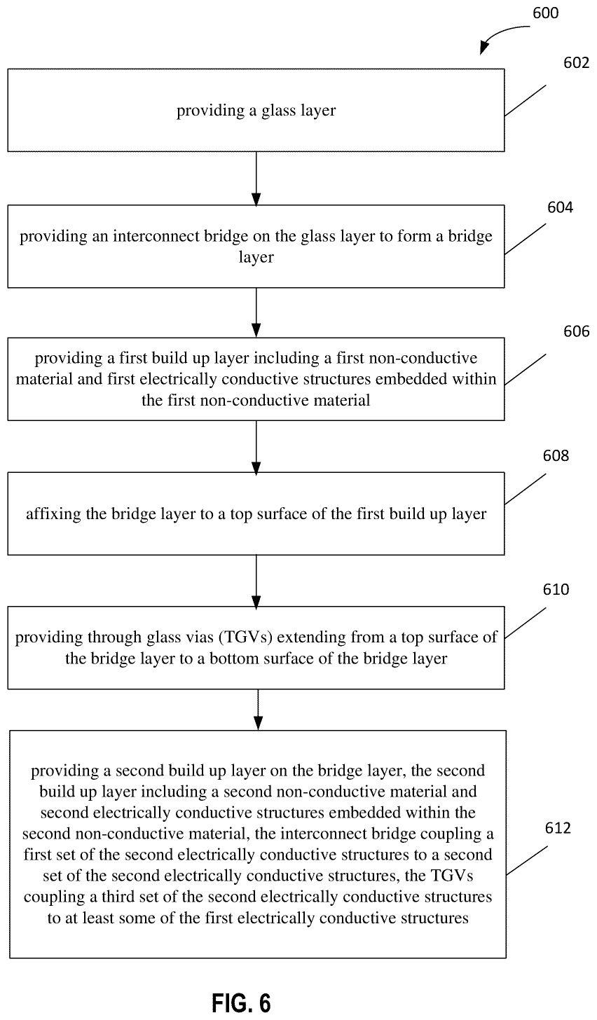

FIG. 6 is a flowchart of a process 600 according to some embodiments. At operation 602, the process includes providing a glass layer. At operation 604, the process includes providing an interconnect bridge on the glass layer to form a bridge layer. At operation 606, the process includes providing a first buildup layer including a first non-conductive material and first electrically conductive structures embedded within the first non-conductive material. At operation 608, the process includes affixing the bridge layer to a top surface of the first buildup layer. At operation 610, the process includes providing through glass vias (TGVs) extending from a top surface of the bridge layer to a bottom surface of the bridge layer. At operation 612, the process includes providing a second buildup layer on the bridge layer, the second buildup layer including a second non-conductive material and second electrically conductive structures embedded within the second non-conductive material, the interconnect bridge coupling a first set of the second electrically conductive structures to a second set of the second electrically conductive structures, the TGVs coupling a third set of the second electrically conductive structures to at least some of the first electrically conductive structures.

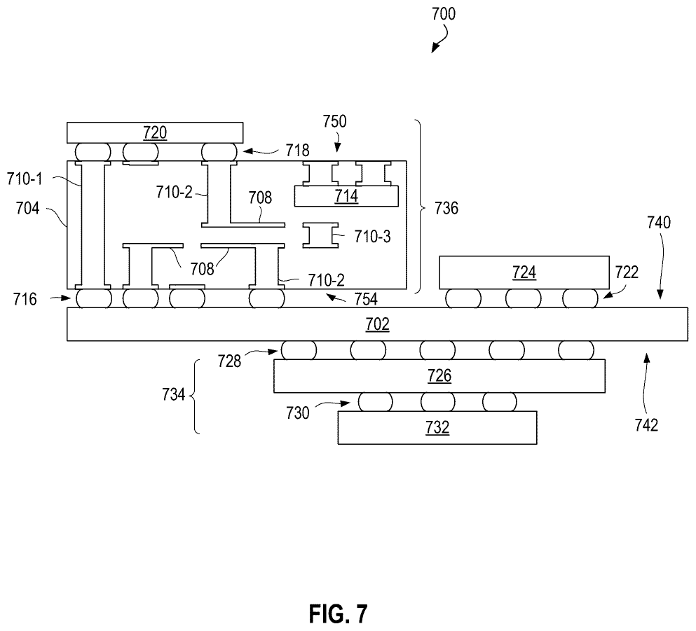

FIG. 7 is a cross-sectional side view of an integrated circuit device assembly 700 that may include one or more integrated circuit structures each including any of the semiconductor packages of embodiments described herein. The integrated circuit device assembly 700 includes a number of components disposed on a circuit board 702 (which may be a motherboard, system board, mainboard, etc.). The integrated circuit device assembly 700 includes components disposed on a first face 740 of the circuit board 702 and an opposing second face 742 of the circuit board 702; generally, components may be disposed on one or both faces 740 and 742. Any of the integrated circuit components discussed below with reference to the integrated circuit device assembly 700 may include an integrated circuit structure including an interconnect structure as described herein.

In some embodiments, the circuit board 702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 702. In other embodiments, the circuit board 702 may be a non-PCB substrate. The integrated circuit device assembly 700 illustrated in FIG. 7 includes a package-on-interposer structure 736 coupled to the first face 740 of the circuit board 702 by coupling components 716. The coupling components 716 may electrically and mechanically couple the package-on-interposer structure 736 to the circuit board 702, and may include solder balls (as shown in FIG. 7), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 736 may include an integrated circuit component 720 coupled to an interposer 704 by coupling components 718. The coupling components 718 may take any suitable form for the application, such as the forms discussed above with reference to the coupling components 716. Although a single integrated circuit component 720 is shown in FIG. 7, multiple integrated circuit components may be coupled to the interposer 704; indeed, additional interposers may be coupled to the interposer 704. The interposer 704 may provide an intervening substrate used to bridge the circuit board 702 and the integrated circuit component 720.

The integrated circuit component 720 may be a packaged or unpackaged integrated circuit product that includes one or more integrated circuit dies. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 720, a single monolithic integrated circuit die comprises solder bumps attached to contacts on the die. The solder bumps allow the die to be directly attached to the interposer 704. The integrated circuit component 720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 720 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 704 may spread connections to a wider pitch or reroute a connection to a different connection. For example, the interposer 704 may couple the integrated circuit component 720 to a set of ball grid array (BGA) conductive contacts of the coupling components 716 for coupling to the circuit board 702. In the embodiment illustrated in FIG. 7, the integrated circuit component 720 and the circuit board 702 are attached to opposing sides of the interposer 704; in other embodiments, the integrated circuit component 720 and the circuit board 702 may be attached to a same side of the interposer 704. In some embodiments, three or more components may be interconnected by way of the interposer 704.

In some embodiments, the interposer 704 may be formed as a PCB, including multiple metal layers separated from one another by layers of dielectric material and interconnected by electrically conductive vias. In some embodiments, the interposer 704 may be formed of an epoxy resin, a fiberglass-reinforced epoxy resin, an epoxy resin with inorganic fillers, a ceramic material, or a polymer material such as polyimide. In some embodiments, the interposer 704 may be formed of alternate rigid or flexible materials that may include the same materials described above for use in a semiconductor substrate, such as silicon, germanium, and other group III-V and group IV materials. The interposer 704 may include metal interconnects 708 and vias 710, including but not limited to through hole vias 710-1 (that extend from a first face 750 of the interposer 704 to a second face 754 of the interposer 704), blind vias 710-2 (that extend from the first or second faces 750 or 754 of the interposer 704 to an internal metal layer), and buried vias 710-3 (that connect internal metal layers).

In some embodiments, the interposer 704 can comprise a silicon interposer. Through silicon vias (TSV) extending through the silicon interposer can connect connections on a first face of a silicon interposer to an opposing second face of the silicon interposer. In some embodiments, an interposer 704 comprising a silicon interposer can further comprise one or more routing layers to route connections on a first face of the interposer 704 to an opposing second face of the interposer 704.

The interposer 704 may further include embedded devices 714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 704. The package-on-interposer structure 736 may take the form of any of the package-on-interposer structures known in the art. In embodiments where the interposer is a non-printed circuit board

The integrated circuit device assembly 700 may include an integrated circuit component 724 coupled to the first face 740 of the circuit board 702 by coupling components 722. The coupling components 722 may take the form of any of the embodiments discussed above with reference to the coupling components 716, and the integrated circuit component 724 may take the form of any of the embodiments discussed above with reference to the integrated circuit component 720.

The integrated circuit device assembly 700 illustrated in FIG. 7 includes a package-on-package structure 734 coupled to the second face 742 of the circuit board 702 by coupling components 728. The package-on-package structure 734 may include an integrated circuit component 726 and an integrated circuit component 732 coupled together by coupling components 730 such that the integrated circuit component 726 is disposed between the circuit board 702 and the integrated circuit component 732. The coupling components 728 and 730 may take the form of any of the embodiments of the coupling components 716 discussed above, and the integrated circuit components 726 and 732 may take the form of any of the embodiments of the integrated circuit component 720 discussed above. The package-on-package structure 734 may be configured in accordance with any of the package-on-package structures known in the art.

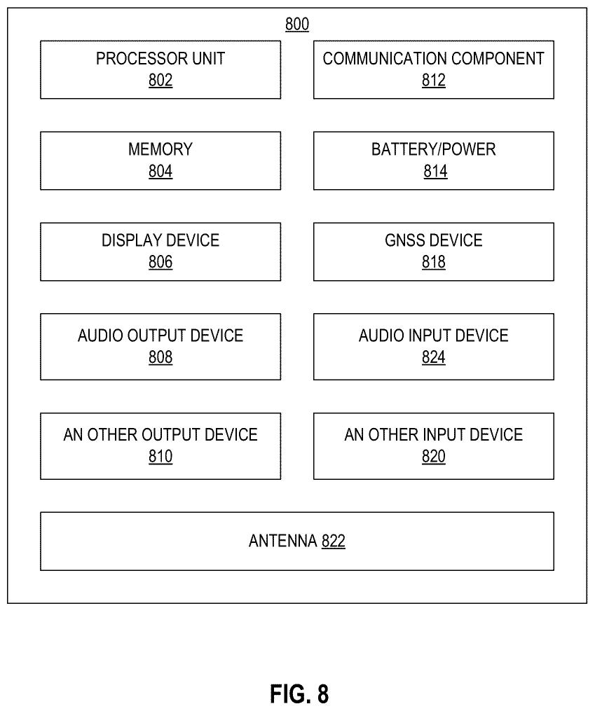

FIG. 8 is a block diagram of an example electrical device 800 that may include one or more of the embodiment semiconductor packages disclosed herein. For example, any suitable ones of the components of the electrical device 800 may include one or more of the integrated circuit device assemblies 700, integrated circuit components 720, and/or embodiment semiconductor packages disclosed herein. A number of components are illustrated in FIG. 8 as included in the electrical device 800, but any one or more of these components may be omitted or duplicated, as suitable for the application. In some embodiments, some or all of the components included in the electrical device 800 may be attached to one or more motherboards mainboards, or system boards. In some embodiments, one or more of these components are fabricated onto a single system-on-a-chip (SoC) die.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

The electrical device 800 may include one or more processor units 802 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the processor unit 802. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 800 can comprise one or more processor units 802 that are heterogeneous or asymmetric to another processor unit 802 in the electrical device 800. There can be a variety of differences between the processing units 802 in a system in terms of a spectrum of metrics of merit including architectural, microarchitectural, thermal, power consumption characteristics, and the like. These differences can effectively manifest themselves as asymmetry and heterogeneity among the processor units 802 in the electrical device 800.

In some embodiments, the electrical device 800 may include a communication component 812 (e.g., one or more communication components). For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other embodiments. The electrical device 800 may include one or more antennas, such as antenna 822 to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 802.3 Ethernet standards). As noted above, the communication component 812 may include multiple communication components. For instance, a first communication component 812 may be dedicated to shorter-range wireless communications such as Wi-Fi or Bluetooth, and a second communication component 812 may be dedicated to longer-range wireless communications such as global positioning system (GPS), EDGE, GPRS, CDMA, WiMAX, LTE, EV-DO, or others. In some embodiments, a first communication component 812 may be dedicated to wireless communications, and a second communication component 812 may be dedicated to wired communications.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System (GNSS) device 818 (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include another output device 810 (or corresponding interface circuitry, as discussed above). Examples of the other output device 810 may include an audio codec, a video codec, a printer, a wired or wireless transmitter for providing information to other devices, or an additional storage device.

The electrical device 800 may include another input device 820 (or corresponding interface circuitry, as discussed above). Examples of the other input device 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

FIG. 10 is a flow chart of a process 1000 according to some embodiments. At operation 1002, the process includes providing a plurality of first dies. At operation 1004, the process includes providing an encapsulation layer on the first dies to form first layer of the semiconductor subassembly. At operation 1006, the process includes providing a first dielectric layer over the first layer to form a first layer and first dielectric layer subassembly. At operation 1008, the process includes providing a passive heat spreader interposer. At operation 1010, the process includes providing a second dielectric layer on the passive heat spreader interposer to form a passive heat spreader interposer and second dielectric layer subassembly. At operation 1012, the process includes forming an interface layer between and mechanically bonding the passive heat spreader interposer and the first layer, the interface layer providing a direct dielectric-to-dielectric bond including a first dielectric sublayer directly adjacent the first layer and formed from the first dielectric layer, and a second dielectric sublayer directly adjacent the first dielectric sublayer, formed from the second dielectric layer, and including an amorphous material. At operation 1014, the process includes providing a second layer including a substrate. At operation 1016, the process includes electrically coupling the substrate to the first dies.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of embodiments has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

In embodiments, the phrase “A is located on B” means that at least a part of A is in direct physical contact or indirect physical contact (having one or more other features between A and B) with at least a part of B.

In the instant description, “A is adjacent to B” means that at least part of A is in direct physical contact with at least a part of B.

In the instant description, “B is between A and C” means that at least part of B is in or along a space separating A and C and that the at least part of B is in direct or indirect physical contact with A and C.

In the instant description, “A is attached to B” means that at least part of A is mechanically attached to at least part of B, either directly or indirectly (having one or more other features between A and B).

The use of reference numerals separated by a “/”, such as “102/104” for example, is intended to refer to 102 or 104 as appropriate. Otherwise, the forward slash (“/”) as used herein means “and/or.”

The use of the techniques and structures provided herein can be detected using tools such as: electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, such tools can indicate an integrated circuit including at least one semiconductor package including an interconnect bridge.

In some embodiments, the techniques, processes and/or methods described herein can be detected based on the structures formed therefrom. In addition, in some embodiments, the techniques and structures described herein can be detected based on the benefits derived therefrom. Numerous configurations and variations will be apparent in light of this disclosure.

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “according to some embodiments,” “in accordance with embodiments,” or “in embodiments,” which may each refer to one or more of the same or different embodiments. Furthermore, the terms “comprising,” “including,” “having,” and the like, as used with respect to embodiments of the present disclosure, are synonymous.

“Coupled” as used herein means that two or more elements are in direct physical contact, or that that two or more elements indirectly physically contact each other, but yet still cooperate or interact with each other (i.e. one or more other elements are coupled or connected between the elements that are said to be coupled with each other). The term “directly coupled” means that two or more elements are in direct contact.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 107 Siemens per meter (S/m) at 20 degrees Celsius. Examples of such materials include Cu, Ag, Al, Au, W, Zn and Ni.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices. The term “signal” may refer to at least one current signal, voltage signal, magnetic signal, or data/clock signal. The meaning of “a,” “an,” and “the” include plural references. The meaning of “in” includes “in” and “on.”

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For purposes of the embodiments, any transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, eFET, etc., may be used without departing from the scope of the disclosure. The term “MN” indicates an n-type transistor (e.g., nMOS, NPN BJT, etc.) and the term “MP” indicates a p-type transistor (e.g., pMOS, PNP BJT, etc.).

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

### EXAMPLES

Some non-limiting example embodiments are set forth below.

Example 1 includes a microelectronic structure including: a first buildup layer and a second buildup layer, the first buildup layer including a first non-conductive material and first electrically conductive structures embedded within the first non-conductive material, and the second buildup layer including a second non-conductive material and second electrically conductive structures embedded within the second non-conductive material; and a bridge layer including a glass material extending across a width thereof, the bridge layer between the first buildup layer and the second buildup layer and comprising: an interconnect bridge including third electrically conductive structures coupling a first set of the first electrically conductive structures to a second set of the first electrically conductive structures; and through glass vias (TGVs) extending from a top surface thereof to a bottom surface thereof, the TGVs coupling a third set of the first electrically conductive structures to at least some of the second electrically conductive structures.

Example 2 includes the subject matter of Example 1, wherein the bridge layer extends along an entire width of at least one of the first buildup layer or the second buildup layer.

Example 3 includes the subject matter of Example 1, wherein the bridge layer extends along less than an entire width of individual ones of the first buildup layer and the second buildup layer.

Example 4 includes the subject matter of any one of Examples 1-3, wherein the third electrically conductive structures are embedded in the glass material of the bridge layer.

Example 5 includes the subject matter of any one of Examples 1-3, wherein: the bridge layer defines a cavity therein; and the interconnect bridge includes a glass body, the third electrically conductive structures embedded in the glass body, the glass body in the cavity of the bridge layer.

Example 6 includes the subject matter of any one of Examples 1-3, further including a core layer, the first buildup layer, the second buildup layer, and the bridge layer on a top surface or on a bottom surface of the core layer.

Example 7 includes the subject matter of any one of Examples 1-3, the bridge layer including through glass vias (TGVs) extending therethrough, the TGVs in registration with vias of the second buildup layer.

Example 8 includes the subject matter of Example 7, wherein the vias of the second buildup layer include an underetch region sharing a surface with a bottom surface of a material of the bridge layer.

Example 9 includes the subject matter of any one of Examples 1-3, further including a core layer, the bridge layer being part of the core layer.

Example 10 includes the subject matter of Example 9, wherein the third electrically conductive structures include bridge vias extending from a bottom region of the interconnect bridge to the second electrically conductive structures.

Example 11 includes the subject matter of Example 10, wherein individual ones of the bridge vias are at least 40 microns in thickness.

Example 12 includes the subject matter of Example 9, wherein the second electrically conductive structures include traces, and the bridge vias abut the traces.

Example 13 includes the subject matter of any one of Examples 1-3, wherein the third electrically conductive structures have dimensions that are at least about ⅓ smaller than corresponding dimensions of the first electrically conductive structures or of the second electrically conductive structures.

Example 14 includes the subject matter of any one of Examples 1-3, wherein the glass material includes silicon.

Example 15 includes the subject matter of Example 14, wherein the glass material further includes at least one of oxygen and boron.

Example 16 includes the subject matter of any one of Examples 1-3, wherein the bridge layer includes a plurality of bridge sublayers, at least one of the bridge sublayers not including glass.

Example 17 includes the subject matter of any one of Examples 1-3, wherein the interconnect bridge includes at least one of active or passive devices.

Example 18 includes a microelectronic structure including: a printed circuit board including: a first buildup layer and a second buildup layer, the first buildup layer including a first non-conductive material and first electrically conductive structures embedded within the first non-conductive material, and the second buildup layer including a second non-conductive material and second electrically conductive structures embedded within the second non-conductive material; and a bridge layer including a glass material extending across a width thereof, the bridge layer between the first buildup layer and the second buildup layer and comprising: an interconnect bridge including third electrically conductive structures electrically coupling a first set of the first electrically conductive structures to a second set of the first electrically conductive structures; and through glass vias (TGVs) extending from a top surface thereof to a bottom surface thereof, the TGVs coupling a third set of the first electrically conductive structures to at least some of the second electrically conductive structures; and a first die and a second die on the printed circuit board, the third electrically conductive structures electrically coupling the first die to the second die.

Example 19 includes the subject matter of Example 18, wherein the bridge layer extends along an entire width of at least one of the first buildup layer or the second buildup layer.

Example 20 includes the subject matter of Example 18, wherein the bridge layer extends along less than an entire width of individual ones of the first buildup layer and the second buildup layer.

Example 21 includes the subject matter of any one of Examples 18-20, wherein the third electrically conductive structures are embedded in the glass material of the bridge layer.

Example 22 includes the subject matter of any one of Examples 18-20, wherein: the bridge layer defines a cavity therein; and the interconnect bridge includes a glass body, the third electrically conductive structures embedded in the glass body, the glass body in the cavity of the bridge layer.

Example 23 includes the subject matter of any one of Examples 18-20, further including a core layer, the first buildup layer, the second buildup layer, and the bridge layer on a top surface or on a bottom surface of the core layer.

Example 24 includes the subject matter of any one of Examples 18-20, the bridge layer including through glass vias (TGVs) extending therethrough, the TGVs in registration with vias of the second buildup layer.

Example 25 includes the subject matter of Example 24, wherein the vias of the second buildup layer include an underetch region sharing a surface with a bottom surface of a material of the bridge layer.

Example 26 includes the subject matter of any one of Examples 18-20, further including a core layer, the bridge layer being part of the core layer.

Example 27 includes the subject matter of Example 26, wherein the third electrically conductive structures include bridge vias extending from a bottom region of the interconnect bridge to the second electrically conductive structures.

Example 28 includes the subject matter of Example 27, wherein individual ones of the bridge vias are at least 40 microns in thickness.

Example 29 includes the subject matter of Example 26, wherein the second electrically conductive structures include traces, and the bridge vias abut the traces.

Example 30 includes the subject matter of any one of Examples 18-20, wherein the third electrically conductive structures have dimensions that are at least about ⅓ smaller than corresponding dimensions of the first electrically conductive structures or of the second electrically conductive structures.

Example 31 includes the subject matter of any one of Examples 18-20, wherein the glass material includes silicon.

Example 32 includes the subject matter of Example 31, wherein the glass material further includes at least one of oxygen and boron.

Example 33 includes the subject matter of any one of Examples 18-20, wherein the bridge layer includes a plurality of bridge sublayers, at least one of the bridge sublayers not including glass.

Example 34 includes the subject matter of any one of Examples 18-20, wherein the interconnect bridge includes at least one of active or passive devices.

Example 35 includes the subject matter of any one of Examples 18-20, wherein the first die and the second die are on an upper surface of the first buildup layer.

Example 36 includes a microelectronic structure including: a printed circuit board including: a first buildup layer and a second buildup layer, the first buildup layer including a first non-conductive material and first electrically conductive structures embedded within the first non-conductive material, and the second buildup layer including a second non-conductive material and second electrically conductive structures embedded within the second non-conductive material; and a bridge layer including a glass material extending across a width thereof, the bridge layer between the first buildup layer and the second buildup layer and comprising: an interconnect bridge including third electrically conductive structures electrically coupling a first set of the first electrically conductive structures to a second set of the first electrically conductive structures; and through glass vias (TGVs) extending from a top surface thereof to a bottom surface thereof, the TGVs coupling a third set of the first electrically conductive structures to at least some of the second electrically conductive structures; a first die and a second die on a first face of the printed circuit board, the third electrically conductive structures electrically coupling the first die to the second die; and a package-on-package structure on a second face of the printed circuit board, the package-on-package structure including a third die and a fourth die, the third die directly coupled to the printed circuit board and between the printed circuit board and the fourth die.

Example 37 includes the subject matter of Example 36, wherein the bridge layer extends along an entire width of at least one of the first buildup layer or the second buildup layer.

Example 38 includes the subject matter of Example 36, wherein the bridge layer extends along less than an entire width of individual ones of the first buildup layer and the second buildup layer.

Example 39 includes the subject matter of any one of Examples 36-38, wherein the third electrically conductive structures are embedded in the glass material of the bridge layer.

Example 40 includes the subject matter of any one of Examples 36-38, wherein: the bridge layer defines a cavity therein; and the interconnect bridge includes a glass body, the third electrically conductive structures embedded in the glass body, the glass body in the cavity of the bridge layer.

Example 41 includes the subject matter of any one of Examples 36-38, further including a core layer, the first buildup layer, the second buildup layer, and the bridge layer on a top surface or on a bottom surface of the core layer.

Example 42 includes the subject matter of any one of Examples 36-38, the bridge layer including through glass vias (TGVs) extending therethrough, the TGVs in registration with vias of the second buildup layer.

Example 43 includes the subject matter of Example 42, wherein the vias of the second buildup layer include an underetch region sharing a surface with a bottom surface of a material of the bridge layer.

Example 44 includes the subject matter of any one of Examples 36-38, further including a core layer, the bridge layer being part of the core layer.

Example 45 includes the subject matter of Example 44, wherein the third electrically conductive structures include bridge vias extending from a bottom region of the interconnect bridge to the second electrically conductive structures.

Example 46 includes the subject matter of Example 45, wherein individual ones of the bridge vias are at least 40 microns in thickness.

Example 47 includes the subject matter of Example 45, wherein the second electrically conductive structures include traces, and the bridge vias abut the traces.

Example 48 includes the subject matter of any one of Examples 36-38, wherein the third electrically conductive structures have dimensions that are at least about ⅓ smaller than corresponding dimensions of the first electrically conductive structures or of the second electrically conductive structures.

Example 49 includes the subject matter of any one of Examples 36-38, wherein the glass material includes silicon.

Example 50 includes the subject matter of Example 49, wherein the glass material further includes at least one of oxygen and boron.

Example 51 includes the subject matter of any one of Examples 36-38, wherein the bridge layer includes a plurality of bridge sublayers, at least one of the bridge sublayers not including glass.

Example 52 includes the subject matter of any one of Examples 36-38, wherein the interconnect bridge includes at least one of active or passive devices.

Example 53 includes method of fabricating a microelectronic structure including: providing a glass layer; providing an interconnect bridge on the glass layer to form a bridge layer; providing a first buildup layer including a first non-conductive material and first electrically conductive structures embedded within the first non-conductive material; affixing the bridge layer to a top surface of the first buildup layer; providing through glass vias (TGVs) extending from a top surface of the bridge layer to a bottom surface of the bridge layer; and providing a second buildup layer on the bridge layer, the second buildup layer including a second non-conductive material and second electrically conductive structures embedded within the second non-conductive material, the interconnect bridge coupling a first set of the second electrically conductive structures to a second set of the second electrically conductive structures, the TGVs coupling a third set of the second electrically conductive structures to at least some of the first electrically conductive structures.

Example 54 includes the subject matter of Example 53, wherein the bridge layer extends along an entire width of at least one of the first buildup layer or the second buildup layer.

Example 55 includes the subject matter of Example 53, wherein the bridge layer extends along less than an entire width of individual ones of the first buildup layer and the second buildup layer.

Example 56 includes the subject matter of any one of Examples 53-55, wherein the glass layer is a first sublayer, and wherein providing the interconnect bridge includes patterning, on a top surface of the glass layer, a second sublayer along with electrical features of the interconnect bridge.

Example 57 includes the subject matter of any one of Examples 53-55, wherein the interconnect bridge includes a bridge body having electrical features therein, and wherein providing the interconnect bridge includes; forming a cavity in the glass layer; and placing the bridge body inside the cavity.

Example 58 includes the subject matter of any one of Examples 53-55, further including providing a core layer, and providing the first buildup layer, the second buildup layer, and the bridge layer on a top surface or on a bottom surface of the core layer.

Example 59 includes the subject matter of any one of Examples 53-55, further including: providing through glass via (TGV) openings extending through the bridge layer; patterning the first buildup layer using the TGV openings to provide via openings in the first buildup layer self-aligned to the TGV openings; and providing an electrically conductive material in the TGV openings and in the via openings to provide corresponding TGVs and vias therefrom.

Example 60 includes the subject matter of Example 59, wherein providing the via openings includes using a dry etch process, and wherein the vias of the second buildup layer include an underetch region sharing a surface with a bottom surface of a material of the bridge layer.

Example 61 includes the subject matter of any one of Examples 53-55, wherein the bridge layer corresponds to a core layer of the microelectronic structure.

Example 62 includes the subject matter of Example 61, further including providing bridge vias extending in the bridge layer from a bottom region of the interconnect bridge to the first electrically conductive structures.

Example 63 includes the subject matter of Example 62, wherein individual ones of the bridge vias are at least 40 microns in thickness.

Example 64 includes the subject matter of Example 61, wherein the first electrically conductive structures include traces, and the bridge vias abut the traces.

Example 65 includes the subject matter of any one of Examples 53-55, wherein electrically conductive structures of the interconnect bridge have dimensions that are at least about ⅓ smaller than corresponding dimensions of the first electrically conductive structures or of the second electrically conductive structures.

Example 66 includes the subject matter of any one of Examples 53-55, wherein the glass layer includes silicon.

Example 67 includes the subject matter of Example 66, wherein the glass layer further includes at least one of oxygen and boron.

Example 68 includes the subject matter of any one of Examples 53-55, wherein the bridge layer includes a plurality of bridge sublayers, at least one of the bridge sublayers not including glass.

Example 69 includes the subject matter of any one of Examples 53-55, wherein the interconnect bridge includes at least one of active or passive devices.

What is claimed is:

1. A microelectronic structure including:
a first buildup layer and a second buildup layer, the first buildup layer including a first non-conductive material and first electrically conductive structures embedded within the first non-conductive material, and the second buildup layer including a second non-conductive material and second electrically conductive structures embedded within the second non-conductive material; and
a bridge layer including a glass material extending across a width thereof, the bridge layer between the first buildup layer and the second buildup layer and comprising:
an interconnect bridge including third electrically conductive structures coupling a first set of the first electrically conductive structures to a second set of the first electrically conductive structures; and
through glass vias (TGVs) extending from a top surface thereof to a bottom surface thereof, the TGVs coupling a third set of the first electrically conductive structures to at least some of the second electrically conductive structures.

2. The microelectronic structure of claim 1, wherein the bridge layer extends along an entire width of at least one of the first buildup layer or the second buildup layer.

3. The microelectronic structure of claim 1, wherein the third electrically conductive structures are embedded in the glass material of the bridge layer.

4. The microelectronic structure of claim 1, wherein:
the bridge layer defines a cavity therein; and
the interconnect bridge includes a glass body, the third electrically conductive structures embedded in the glass body, the glass body in the cavity of the bridge layer.

5. The microelectronic structure of claim 1, further including a core layer, the first buildup layer, the second buildup layer, and the bridge layer on a top surface or on a bottom surface of the core layer.

6. The microelectronic structure of claim 1, the bridge layer including through glass vias (TGVs) extending therethrough, the TGVs in registration with vias of the second buildup layer.

7. The microelectronic structure of claim 6, wherein the vias of the second buildup layer include an underetch region sharing a surface with a bottom surface of a material of the bridge layer.

8. The microelectronic structure of claim 1, further including a core layer, the bridge layer being part of the core layer.

9. The microelectronic structure of claim 8, wherein the third electrically conductive structures include bridge vias extending from a bottom region of the interconnect bridge to the second electrically conductive structures.

10. The microelectronic structure of claim 9, wherein individual ones of the bridge vias are at least 40 microns in thickness.

11. The microelectronic structure of claim 8, wherein the second electrically conductive structures include traces, and the bridge vias abut the traces.

12. The microelectronic structure of claim 1, wherein the third electrically conductive structures have dimensions that are at least about ⅓ smaller than corresponding dimensions of the first electrically conductive structures or of the second electrically conductive structures.

13. A semiconductor package, comprising:
a printed circuit board including:
a first buildup layer and a second buildup layer, the first buildup layer including a first non-conductive material and first electrically conductive structures embedded within the first non-conductive material, and the second buildup layer including a second non-conductive material and second electrically conductive structures embedded within the second non-conductive material; and
a bridge layer including a glass material extending across a width thereof, the bridge layer between the first buildup layer and the second buildup layer and comprising:
an interconnect bridge including third electrically conductive structures electrically coupling a first set of the first electrically conductive structures to a second set of the first electrically conductive structures; and
through glass vias (TGVs) extending from a top surface thereof to a bottom surface thereof, the TGVs coupling a third set of the first electrically conductive structures to at least some of the second electrically conductive structures; and
a first die and a second die on the printed circuit board, the third electrically conductive structures electrically coupling the first die to the second die.

14. The semiconductor package of claim 13, wherein the third electrically conductive structures are embedded in the glass material of the bridge layer.

15. The semiconductor package of claim 13, further including a core layer, the bridge layer being part of the core layer, wherein the third electrically conductive structures include bridge vias extending from a bottom region of the interconnect bridge to the second electrically conductive structures, individual ones of the bridge vias being at least 40 microns in thickness.

16. The semiconductor package of claim 13, wherein the glass material includes silicon.

17. The semiconductor package of claim 16, wherein the glass material further includes at least one of oxygen and boron.

18. An integrated circuit (IC) device assembly including:
a printed circuit board including:
a first buildup layer and a second buildup layer, the first buildup layer including a first non-conductive material and first electrically conductive structures embedded within the first non-conductive material, and the second buildup layer including a second non-conductive material and second electrically conductive structures embedded within the second non-conductive material; and
a bridge layer including a glass material extending across a width thereof, the bridge layer between the first buildup layer and the second buildup layer and comprising:
an interconnect bridge including third electrically conductive structures electrically coupling a first set of the first electrically conductive structures to a second set of the first electrically conductive structures; and
through glass vias (TGVs) extending from a top surface thereof to a bottom surface thereof, the TGVs coupling a third set of the first electrically conductive structures to at least some of the second electrically conductive structures;
a first die and a second die on a first face of the printed circuit board, the third electrically conductive structures electrically coupling the first die to the second die; and
a package-on-package structure on a second face of the printed circuit board, the package-on-package structure including a third die and a fourth die, the third die directly coupled to the printed circuit board and between the printed circuit board and the fourth die.

19. The IC device assembly of claim 18, wherein the bridge layer extends along an entire width of at least one of the first buildup layer or the second buildup layer.

20. The IC device assembly of claim 18, wherein the bridge layer extends along less than an entire width of individual ones of the first buildup layer and the second buildup layer.

21. A method of fabricating a microelectronic structure including:
providing a glass layer;
providing an interconnect bridge on the glass layer to form a bridge layer;
providing a first buildup layer including a first non-conductive material and first electrically conductive structures embedded within the first non-conductive material;
affixing the bridge layer to a top surface of the first buildup layer;
providing through glass vias (TGVs) extending from a top surface of the bridge layer to a bottom surface of the bridge layer; and
providing a second buildup layer on the bridge layer, the second buildup layer including a second non-conductive material and second electrically conductive structures embedded within the second non-conductive material, the interconnect bridge coupling a first set of the second electrically conductive structures to a second set of the second electrically conductive structures, the TGVs coupling a third set of the second electrically conductive structures to at least some of the first electrically conductive structures.

22. The method of claim 21, wherein the glass layer is a first sublayer, and wherein providing the interconnect bridge includes patterning, on a top surface of the glass layer, a second sublayer along with electrical features of the interconnect bridge.

23. The method of claim 21, wherein the interconnect bridge includes a bridge body having electrical features therein, and wherein providing the interconnect bridge includes;
forming a cavity in the glass layer; and
placing the bridge body inside the cavity.

24. The method of claim 21 further including:
providing through glass via (TGV) openings extending through the bridge layer;
patterning the first buildup layer using the TGV openings to provide via openings in the first buildup layer self-aligned to the TGV openings; and
providing an electrically conductive material in the TGV openings and in the via openings to provide corresponding TGVs and vias therefrom.

25. The method of claim 24, wherein providing the via openings includes using a dry etch process, and wherein the vias of the second buildup layer include an underetch region sharing a surface with a bottom surface of a material of the bridge layer.
